(19) United States
(12) Patent Application Publication
(10) Pub. No.: US 2025/0098355 A1
(43) Pub. Date: Mar. 20, 2025

(54) CHIP PACKAGE STRUCTURE AND METHOD OF MANUFACTURING THE SAME

(71) Applicant: SAMSUNG ELECTRONICS CO.,LTD., Suwon-si (KR)

(72) Inventor: Weizhong ZHOU, Suzhou (CN)

(73) Assignees: SAMSUNG ELECTRONICS CO.,LTD., Suwon-si (KR); Samsung Semiconductor China Research & Development Co., LTD., Suzhou (CN)

(21) Appl. No.: 18/444,062

(22) Filed: Feb. 16, 2024

(30) Foreign Application Priority Data
Sep. 18, 2023 (CN) 202311200594.6

(51) Int. Cl. H01L 27/146

(52) U.S. Cl. CPC H10F 39/811; H10F 39/804

(57) ABSTRACT

A chip package structure and a method of manufacturing the same are provided. The chip package structure includes a substrate; a chip spaced from the substrate and having a first surface, a second surface and a side surface, the first surface of the chip including a photosensitive area and a non-photosensitive area surrounding the photosensitive area; a molding layer having a first surface and a second surface, the molding layer provided on the non-photosensitive area of the chip and the side surface of the chip.

### CROSS-REFERENCE TO RELATED APPLICATION

This application is based on and claims priority under 35 USC § 119 to Chinese Patent Application No. 202311200594.6 filed on Sep. 18, 2023, in the China National Intellectual Property Administration, the contents of which being incorporated by reference herein in their entirety.

### BACKGROUND

### Field

The disclosure relates to a chip package structure and a method of manufacturing the chip package structure, and more particularly, to a fan-out image sensor chip package and a method of manufacturing the fan-out image sensor chip package.

### Description of Related Art

With recent developments in the electronic industry, a demand for a semiconductor package, such as a chip package structure, with small size and high performance is increasing. In this regard, a semiconductor package implementing a fan-out package technique can reduce the volume of the semiconductor package structure.

In related art chip package structures, for example, in the complementary metal oxide semiconductor image sensor (CMOS image sensor, abbreviated as CIS) chip package structure, it is usually necessary to apply a dam sealing technique or a through-silicon via (TSV) technique. The sealant used in the dam sealing technique easily overflows, and pollutes the photosensitive area of CIS chip, such that the performance of photosensitive elements is affected. On the other hand, TSV technique has the drawbacks of processing difficulty and high cost.

### SUMMARY

One or more aspect of the disclosure may provide a chip package structure with improved reliability and simplified structure and manufacturing process.

One or more aspect of the disclosure may provide a method of manufacturing a chip package structure with improved reliability and simplified structure and manufacturing process.

According to an aspect of the disclosure, there is provided a semiconductor chip package including: a substrate; a semiconductor chip provided on the substrate and spaced apart from the substrate, the semiconductor chip having a first surface facing the substrate, a second surface facing a direction opposite to the first surface, and a side surface e connecting the first surface and the second surface, the first surface of the semiconductor chip comprising a first area and a second area surrounding the first area; a molding layer having a first surface facing the substrate and a second surface opposite to the first surface, the molding layer provided on the second area of the semiconductor chip and the side surface of the semiconductor chip; and an adhesive layer provided between the substrate and the molding layer.

According to another aspect of the disclosure, there is provided a method of manufacturing a semiconductor chip package, the method including: attaching a semiconductor chip to a first substrate, which is a carrier substrate, the semiconductor chip having a second surface facing the first substrate, a first surface facing a direction opposite to the second surface, and a side surface connecting the first surface and the second surface, and the first surface of the semiconductor chip including a first area and a second area surrounding the first area; forming a protective layer on the first area of the semiconductor chip; forming a molding layer around the semiconductor chip, the molding layer having a second surface facing the first substrate and a first surface facing a direction opposite to the second surface, the molding layer provided on the second area of the semiconductor chip and the side surface of the semiconductor chip; removing the protective layer and the first substrate; and bonding the first surface of the molding layer to a second substrate by providing an adhesive layer between the second substrate and the molding layer.

According to another aspect of the disclosure, there is a method of manufacturing a semiconductor chip package, including: attaching a semiconductor chip to a first substrate, which is a carrier substrate, the semiconductor chip having a second surface facing the first substrate, a first surface facing a direction opposite to the second surface, and a side surface connecting the first surface and the second surface, and the first surface of the semiconductor chip including a photosensitive area and a non-photosensitive area surrounding the photosensitive area; forming a light transmitting layer on the photosensitive area of the semiconductor chip; forming a molding layer around the semiconductor chip, the molding layer having a second surface facing the first substrate and a first surface facing a direction opposite to the second surface, the molding layer provided on the non-photosensitive area of the semiconductor chip and the side surface of the semiconductor chip; removing the first substrate; and bonding the first surface of the molding layer to a second substrate by providing an adhesive layer between a second substrate and the molding layer.

### BRIEF DESCRIPTION OF DRAWINGS

The above and other aspects, features and advantages of the disclosure will be apparent from description of example embodiments in combination with the accompanying drawings, in which:

FIG. 1 is a cross-sectional view illustrating a chip package structure according to an example embodiment of the disclosure;

FIG. 2 is a cross-sectional view illustrating a chip package structure according to another example embodiment of the disclosure;

FIG. 3 is a flowchart illustrating a method of manufacturing the chip package structure according to an example embodiment of the disclosure;

FIGS. 4 to 10 are cross-sectional views illustrating operations of the method of manufacturing the chip package structure according to an example embodiment of the disclosure;

FIG. 11 is a flowchart illustrating a method of manufacturing the chip package structure according to another example embodiment of the disclosure; and

FIGS. 12 and 13 are cross-sectional views illustrating operations of the method of manufacturing the chip package structure according to another example embodiment of the disclosure.

### DETAILED DESCRIPTION

Hereinafter, various example embodiments of the disclosure will be described more fully with reference to the drawings. The disclosure, however, may be embodied in various different forms, and should not be construed as being limited to the example embodiments set forth herein. Rather, the following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. In the drawings, the sizes of layers and regions may be exaggerated for clarity.

Throughout the specification, in an example case in which a component is described as being “connected to,” or “coupled to” another component, it may be directly “connected to,” or “coupled to” the other component, or there may be one or more other components intervening therebetween. In contrast, in an example case in which an element is described as being “directly connected to,” or “directly coupled to” another element, there can be no other elements intervening therebetween. Likewise, similar expressions, for example, “between” and “immediately between,” and “adjacent to” and “immediately adjacent to,” are also to be construed in the same way. As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all example embodiments are not limited thereto.

The embodiments of the disclosure are example embodiments, and thus, the disclosure is not limited thereto and may be realized in various other forms. As is traditional in the field, embodiments may be described and illustrated in terms of blocks, as shown in the drawings, which carry out a described function or functions. These blocks, which may be referred to herein as units or modules or the like, or by names such as device, logic, circuit, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Spatially relative terms, such as “beneath,” “below,” “lower,” “above,” “upper,” and the like, may be used herein for ease of description to describe a spatial relation between a first element and a second element, or a spatial relation between a first feature and a second feature as illustrated in the figures. In some cases, the spatially relative terms may be used to describe a spatial relation between a first element and a plurality of second elements, or a spatial relation between a first feature and a plurality second features as illustrated in the figures. It will be understood that the spatially relative terms are intended to encompass different orientations of the device in use or in operation, in addition to the orientation depicted in the figures. For example, in a case in which the device in the figures is turned over, elements described as “below” or “beneath” other elements would then be oriented “above” the other elements. Thus, the example terms “below” can encompass both orientations of “above” and “below”. The device may be otherwise oriented (e.g., rotated 90 degrees or at other orientations) and the spatially relative descriptors used herein should be interpreted accordingly.

Although the term “same,” “equal” or “identical” is used in description of example embodiments, it should be understood that some imprecisions may exist. As such, in a case in which one element or value is referred to as being the same as another element or value, it should be understood that the element or value is the same as the another element within a desired manufacturing or operational tolerance range (e.g., ±10%).

In an example case in which the term “about” or “substantially” is used in this specification in connection with a numerical value, it is intended that the associated numerical value includes a manufacturing or operational tolerance (e.g., ±10%) around the stated numerical value. Moreover, in an example case in which the term “about” or “substantially” is used in connection with geometric shapes, it is intended that precision of the geometric shape is not required but that latitude for the shape is within the scope of the disclosure. Further, regardless of whether numerical values or shapes are limited by “about” or “substantially”, it will be understood that these values or shapes should be construed as including a manufacturing or operational tolerance (e.g., ±10%) around the stated numerical values or shapes.

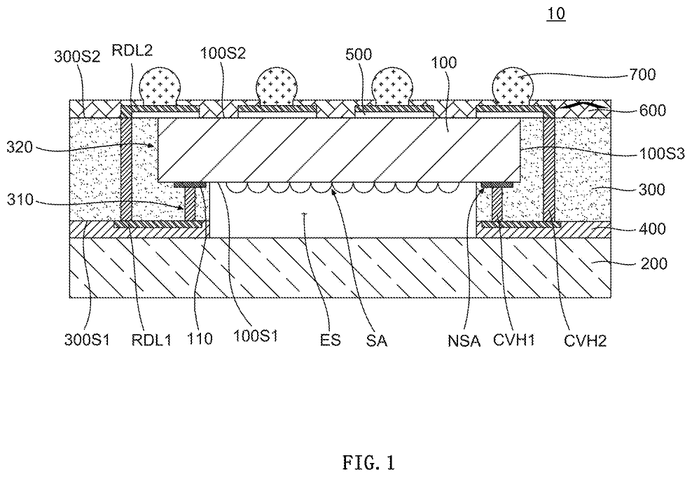

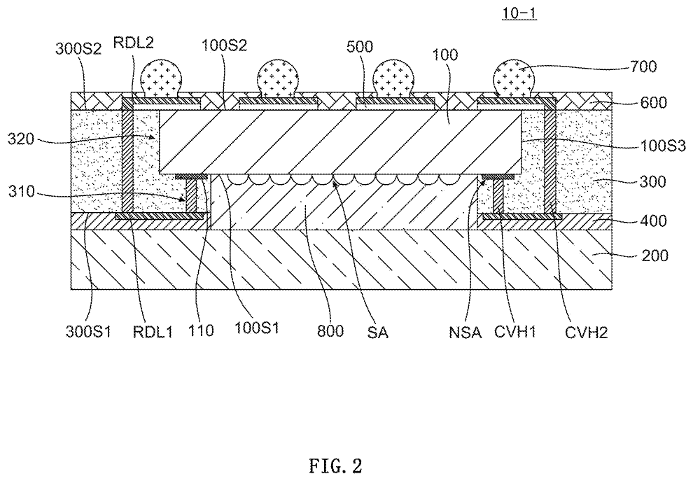

Hereinafter, a chip package structure according to the disclosure will be described with reference to FIGS. 1 and 2.

FIG. 1 is a cross-sectional view illustrating a chip package structure according to an example embodiment of the disclosure.

Referring to FIG. 1, a chip package structure 10 according to an example embodiment includes a chip 100, a substrate 200, a molding layer 300, and an adhesive layer 400.

The chip 100 may include a complementary metal-oxide-semiconductor (CMOS) image sensor (CIS) chip. The CIS chip may be configured to receive external light and convert the received light it into an electrical signal. The chip 100 may have a first surface 10051, a second surface 10052, or referred to as a passive surface or a back surface) opposite to the first surface 10051, and a side surface 10053 connecting the first surface 10051 and the second surface 10052. The first surface 10051 may be a lower surface of the chip 100 in FIG. 1, or referred to as an active surface or a front surface of the chip 100 and the second surface 10052 may be an upper surface of the chip 100 in FIG. 1, or referred to as a passive surface or a back surface of the chip 100. In an example embodiment, the chip 100 may be substantially in a cuboid shape, but the disclosure is not limited thereto. As such, the chip 100 may have another shape according to another embodiment.

The first surface 10051 of the chip 100 may include a photosensitive area SA and a non-photosensitive area NSA surrounding the photosensitive area SA. For example, the photosensitive area SA may be provided in a central region of the first surface 10051 of the chip 100, and the non-photosensitive area NSA may be provided in an edge region (or a peripheral region) of the first surface 100S1 of the chip 100. A photosensitive element capable of converting light into an electrical signal may be provided in the photosensitive area SA. A chip pad 110 may be provided in the non-photosensitive area NSA.

The substrate 200 is provided below the chip 100 and is spaced apart from the chip 100. One surface of the substrate 200 (e.g. the upper surface of the substrate 200 in FIG. 1) faces the first surface 100S1 of the chip 100 with an empty space ES between the substrate 200 and the chip 100. For example, a gap may be provided the upper surface of the substrate 200 and the lower surface 100S1 of chip 100. The interior of the empty space ES may be filled with a gas such as air, nitrogen, inert gas, and/or the like. According to another embodiment, other light transmitting elements may also be provided between the first surface 100S1 of the chip 100 and the substrate 200.

According to an embodiment, at least a region of the substrate 200 corresponding to the photosensitive area SA of the chip 100 may have excellent light transmittance. Accordingly, at least a part or the entire of the region of the substrate 200 may include a material having a high light transmittance. For example, the region of the substrate 200 corresponding to the photosensitive area SA of the chip 100 may be composed of a material having a high light transmittance, while the region corresponding to the non-photosensitive area NSA may be composed of a material having a relatively low light transmittance or an opaque material. Here, the region of the substrate 200 corresponding to the photosensitive area SA of the chip 100 may be a first region of the substrate 200 overlapping the photosensitive area SA of the chip 100 in a plan view, and the region corresponding to the non-photosensitive area NSA may be a second region of the substrate 200 overlapping the non-photosensitive area NSA of the chip 100 in the plan view. However, the disclosure is not limited thereto, and the substrate 200 may be made of a material having a high light transmittance as a whole. For example, the substrate 200 may be a transparent substrate, such as a glass substrate, a polymethyl methacrylate (PMMA) substrate, or the like, made of a transparent material.

The substrate 200 may have a shape corresponding to (similar to) the chip 100. In an example embodiment, the substrate 200 may be substantially in a cuboid shape, but the disclosure is not limited thereto. As such, the chip 100 may have another shape according to another embodiment.

The molding layer 300 may be provided on the substrate 200 and may surround the chip 100. The molding layer 300 may include or be formed of an epoxy molding compound (EMC). The molding layer 300 may have a first surface 300S1 facing the substrate 200 and a second surface 300S2 opposite to the first surface 300S1.

The molding layer 300 may include a first molding portion 310 and a second molding portion 320. The first molding portion 310 may be provided on the non-photosensitive area NSA of the chip 100, and the second molding portion 320 may be provided on the side surface 100S3 of the chip 100. As shown in FIG. 1, the second molding portion 320 is provided adjacent an outer surface of the first molding portion 310. For example, the first molding portion 310 may cover the non-photosensitive area NSA of the chip 100, and the second molding portion 320 may cover the side surface 100S3 of the chip 100 and the outer surface of the first molding portion 310.

The first molding portion 310 and the second molding portion 320 are integrated with each other. For example, the first molding portion 310 and the second molding portion 320 may be formed simultaneously in the same process, and may include the same material with each other. However, the disclosure is not limited thereto, and as such, according to another embodiment, the first molding portion 310 and the second molding portion 320 may be formed separately or the first molding portion 310 and the second molding portion 320 may have different materials.

As shown in FIG. 1, the second surface 300S2 of the molding layer 300 and the second surface 100S2 of the chip 100 are coplanar with each other. In addition, a lower surface of the first molding portion 310 (i.e., a surface facing the substrate 200) and a lower surface of the second molding portion 320 (i.e., a surface facing the substrate 200) are coplanar with each other to form the first surface 300S1 of the molding layer 300.

The adhesive layer 400 may be provided between the substrate 200 and the molding layer 300. The adhesive layer 400 may be an adhesive member for bonding the substrate 200 and the molding layer 300 to each other. For example, the adhesive layer 400 may be a non-conductive film (NCF) a non-conductive adhesive (NCP) or a capillary underfill (CUF) material. As shown in FIG. 1, the adhesive layer 400 may be provided between the first surface 300S1 of the molding layer 300 and the first surface 100S1 of the substrate 200. In the plan view, the shape of the adhesive layer 400 may completely correspond to the shape of the first surface 300S1 of the molding layer 300. Here, “completely correspond to” means having substantially the same shape, but there may be fine differences due to the manufacturing process. For example, in the plan view, the adhesive layer 400 may completely overlap the molding layer 300.

As shown in FIG. 1, the chip package structure 10 may further include a first conductive via CVH1, a second conductive via CVH2, a first redistribution layer RDL1, a second redistribution layer RDL2, a buffer layer 500, a solder resist layer 600, and a solder ball 700.

The first conductive via CVH1 and the second conductive via CVH2 may be formed in the molding layer 300. For example, the first conductive via CVH1 may be formed in the first molding portion 310, and may extend from the first surface 300S1 of the molding layer 300 to the first surface 100S1 of the chip 100 and be electrically connected to the chip pad 110. The second conductive via CVH2 may be formed in the second molding portion 320 and extend from the first surface 300S1 of the molding layer 300 to the second surface 300S2 of the molding layer 300.

The first conductive via CVH1 and the second conductive via CVH2 may be formed by filling a conductive material into a through hole formed in the molding layer 300. The first conductive via CVH1 and the second conductive via CVH2 may be formed of a conductive material. For example, the first conductive via CVH1 and the second conductive via CVH2 may include a conductive material, such as metal, metal alloy or conductive metal nitride. For example, the first conductive via CVH1 and the second conductive via CVH2 may include at least one of copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru) or an alloy thereof, but are not limited thereto. For example, the first conductive via CVH1 and the second conductive via CVH2 may include at least one of TaN and TiN, but are not limited thereto. The first conductive via CVH1 and the second conductive via CVH2 may include the same or different materials from each other.

The first redistribution layer RDL1 may be provided on the first surface 300S1 of the molding layer 300. The first redistribution layer RDL1 may electrically connect the first conductive via CVH1 and the second conductive via CVH2 to each other. The second redistribution layer RDL2 may be provided on the second surface 300S2 of the molding layer 300 and the second surface 100S2 of the chip 100. The second redistribution layer RDL2 may be electrically connected to the first redistribution layer RDL1 through the second conductive via CVH2.

While FIG. 1 illustrates an example in which the first redistribution layer RDL1 and the second redistribution layer RDL2 each include a single conductive layer is schematically shown in FIG. 1, the disclosure is not limited thereto. As such, according to another embodiment, the first redistribution layer RDL1 and the second redistribution layer RDL2 may each include a plurality of conductive layers and a plurality of insulating layers stacked on each other, and the plurality of conductive layers may be electrically connected to each other through via holes passing through the insulating layers. The conductive layer may include or be formed of at least one of the conductive materials. For example, the conductive layer may include or be formed of one or more of the conductive materials.

For example, the material of the conductive layer in the first redistribution layer RDL1 and the second redistribution layer RDL2 may include or be formed of at least one of a metal, a metal alloy and a conductive metal nitride. Specific examples of the metal, metal alloy, and conductive metal nitride are the same as those of the materials of the first conductive via CVH1 and the second conductive via CVH2 described above, and the redundancy description will not be repeated herein. The materials of the conductive layers in the first redistribution layer RDL1 and the second redistribution layer RDL2 may be the same as or different from the materials of the first conductive via CVH1 and the second conductive via CVH2.

The chip pad 110 can be fanned out to a conductive layer located on the back surface (i.e., the second surface 100S2) of the chip 100 through the first conductive via CVH1, the second conductive via CVH2, the first redistribution layer RDL1, and the second redistribution layer RDL2. For example, the chip pad 110 may use a fan-out structure or a fan-out-technique to electrically connect to a conductive layer located on the back surface (i.e., the second surface 100S2) of the chip 100 through the first conductive via CVH1, the second conductive via CVH2, the first redistribution layer RDL1, and the second redistribution layer RDL2.

The buffer layer 500 may be provided between the second redistribution layer RDL2 and the second surface 300S2 of the molding layer 300 and between the second redistribution layer RDL2 and the second surface 100S2 of the chip 100. The buffer layer 500 may be used to improve the bonding force between the second redistribution layer RDL2, and the molding layer 300 and the chip 100. The buffer layer 500 may include a silicide such as silicon oxide, silicon nitride, silicon oxynitride or tetraethyl orthosilicate (TEOS) or a photoimageable resin such as a photoimageable dielectric (PID) or a photosensitive polyimide (PSPI).

The solder resist layer 600 may be provided on the second surface 300S2 of the molding layer 300 and the second surface 100S2 of the chip 100. For example, the solder resist layer 500 may be provided to cover the second redistribution layer RDL2 and the buffer layer 500. In an example, the solder resist layer 600 may be provided on a side surface of the buffer layer 500 and the second redistribution layer RDL2. The solder resist layer 600 have an opening 6000P that exposes a portion of the second redistribution layer RDL2.

The solder ball 700 may be provided on the solder resist layer 600 and electrically connected to the second redistribution layer RDL2 through the opening 6000P of the solder resist layer 600. The solder ball 700 may be provided directly on the second redistribution layer RDL2. For example, the solder ball 700 may include a portion provided on the solder resist layer 600. For example, the solder ball 700 may include a first portion provided directly on the second redistribution layer RDL2 and a second portion provided on the solder resist layer 600. The solder ball 700 may be used as a connection terminal for connecting the second redistribution layer RDL2 with an external device. For example, an electrical signal may be transmitted from the chip 100 to the external device through the chip pad 110, the first conductive via CVH1, the first redistribution layer RDL1, the second conductive via CVH2, the second redistribution layer RDL2, and the solder ball 700, or an electrical signal may be transmitted from the external device to the chip 100 through the solder ball 700, the second redistribution layer RDL2, the second conductive via CVH2, the first redistribution layer RDL1, the first conductive via CVH1, and the chip pad 110.

In a related art structure, in order to prevent an EMC material from overflowing to a photosensitive area of a CIS chip in forming a molding layer, a loop of sealant surrounding the photosensitive area of the chip is usually formed at the edge of an active surface of the chip by a dam sealing technique (or dispensing process). However, the sealant formed by dam sealing technique may pollute the photosensitive area due to overflowing. On the other hand, using TSV technique instead of dam sealing technique to form fan-out package structure may increase the process difficulty and manufacturing cost.

In an example embodiment of the disclosure, a protective layer covering the photosensitive area SA may first be formed on the first surface 100S1 of the chip 100, so that the EMC material is prevented from overflowing to the photosensitive area SA of the chip 100 during forming the molding layer 300. As such, the formed molding layer 300 may include the first molding portion 310 covering the non-photosensitive area NSA of the chip 100, while a sealant formed on the edge of the active surface of the chip 100 may not be included in the finally manufactured chip package structure 10. Therefore, the chip package structure 10 of the disclosure can realize a fan-out type CIS chip package structure without using dam sealing technique, thereby avoiding defects caused by contamination of the photosensitive area by a sealant, so that the chip package structure 10 has improved reliability. In addition, a member formed of a sealant can be omitted in the chip package structure 10, and no additional members are added in the chip package structure 10, so that a chip package structure 10 having a simplified structure can be provided, and a potential failure risk caused by the addition of a member can be avoided.

FIG. 2 is a schematic perspective view illustrating a chip package structure according to another example embodiment of the disclosure.

The chip package structure 10-1 in FIG. 2 differs from the chip package structure 10 in FIG. 1 in that the chip package structure 10-1 does not include an empty space ES. For example, the chip package structure 10-1 may include a light transmitting layer 800 provided between the photosensitive area SA of the chip 100 and the substrate 200.

According to an embodiment, the light transmitting layer 800 may include or be composed of a material having a high light transmittance. For example, the light transmitting layer 800 may include a transparent resin. The light transmitting layer 800 may be provided on the photosensitive area SA of the chip 100. For example, the light transmitting layer 800 may cover the photosensitive area SA of the chip 100. As shown in FIG. 2, the light transmitting layer 800 may contact one surface (for example, the upper surface in FIG. 1) of the substrate 200 and the inner surface of the molding layer 300.

According to an embodiment, by forming the light transmitting layer 800 on the photosensitive area SA of the chip 100 or covering the photosensitive area SA on the first surface 100S1 of the chip 100, it is possible to prevent the EMC material from overflowing to the photosensitive area SA of the chip 100 in forming the molding layer 300. Therefore, there is no need to use a sealing technique to protect the photosensitive area SA of the chip 100, so that defects caused by contamination of the photosensitive area by a sealant used in the dam sealing technique can be avoided. In addition, in the manufacturing process of the chip package structure 10-1, an operation of removing the light transmitting layer 800 is not required, and thus the manufacturing process can be simplified.

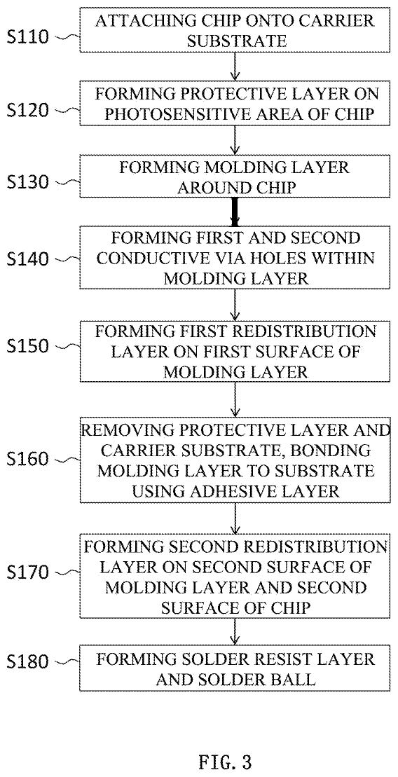

A method of manufacturing a chip package structure according to an example embodiment of the disclosure will be described below with reference to FIGS. 3 to 13

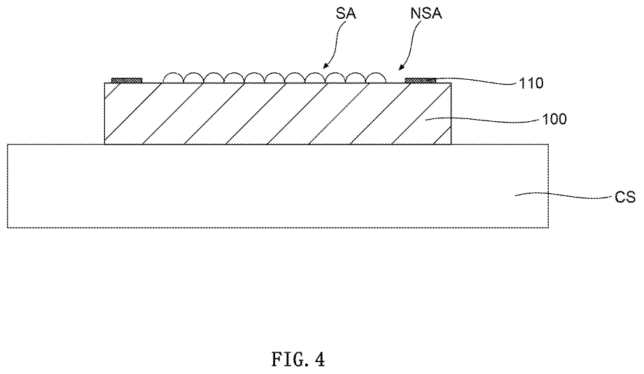

FIG. 3 is a flowchart illustrating a method of manufacturing the chip package structure according to an example embodiment of the disclosure. FIGS. 4 to 10 are cross-sectional views illustrating operations of the method of manufacturing the chip package structure according to an example embodiment of the disclosure. In FIGS. 4 to 10, reference numerals identical to those in FIG. 1 are used to refer to identical elements, and therefore, redundant descriptions are not repeated.

Referring to FIGS. 3 and 4, in operation S110, the method may include attaching a chip 100 to a carrier substrate CS. For example, a second surface 100S2 of the chip 100 may be attached onto the carrier substrate CS, for example, using an adhesive material. As such, the first surface 100S1 of the chip 100 including a photosensitive area SA and a non-photosensitive area NSA is oriented to face a direction opposite to the carrier substrate CS. Photosensitive elements may be provided in the photosensitive area SA of the chip 100, and chip pads 110 may be provided in a non-photosensitive area NSA of the chip 100.

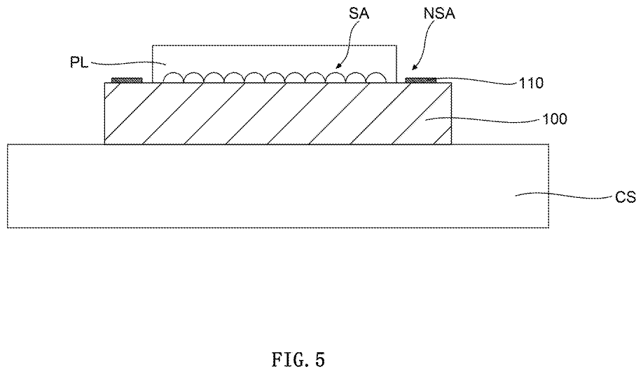

Referring to FIGS. 3 and 5, in operation S120, a protective layer PL may be formed on the photosensitive area SA of the chip 100. The protective layer PL may include or be formed of, for example, a photoresist. For example, the protective layer PL may be formed only on the photosensitive area SA of the chip 100. That is, the protective layer PL may not be formed on the non-photosensitive area NSA of the chip 100. For example, the photosensitive area SA of the chip 100 may be covered, and the non-photosensitive area NSA of the chip 100 may be exposed. According to an embodiment, the protective layer PL may be formed by forming a photoresist layer on an entire first surface 100S1 of the chip 100 and then preforming an etching process using a mask to expose the non-photosensitive area NSA of the chip 100. Accordingly, the non-photosensitive area NSA of the chip 100 may be exposed to the outside.

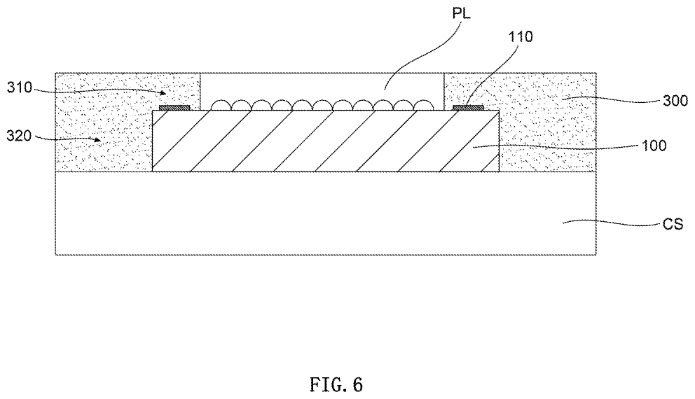

Referring to FIGS. 3 and 6, in operation S130, a molding layer 300 may be formed around the chip 100. The molding layer 300 may include or be formed of an epoxy molding compound (EMC). For example, the molding layer 300 may be formed around the chip 100 using a wafer-level plastic packaging process. However, the disclosure is not limited thereto, and as such, the molding layer 300 may be formed using another type of process. In an example embodiment, the chip 100 may first be encapsulated in a preliminary molding layer along with the protective layer PL, and then a portion of the preliminary molding layer on the first surface 100S1 of the chip 100 may be removed by a planarization process to expose the protective layer PL, so that the molding layer 300 is obtained. According to another embodiment, the molding layer 300 having a surface coplanar with an upper surface of the protective layer PL as shown in FIG. 6 may also be directly formed.

According to an embodiment, since to the protective layer PL is provided on the photosensitive area SA of the chip 100, the molding layer 300 may not be formed on the photosensitive area SA of the chip 100. Meanwhile, since the protective layer PL is provided only on the photosensitive area SA of the chip 100, the molding layer 300 may be formed on the non-photosensitive area NSA of the chip 100. In this case, the molding layer 300 may include a first molding portion 310 provided on the non-photosensitive area NSA of the chip 100 and a second molding portion 320 surrounding a side surface 100S3 of the chip 100 and an outer surface of the first molding portion 310.

According to an embodiment, the first molding portion 310 and the second molding portion 320 may be formed simultaneously in the same process. Therefore, the first molding portion 310 and the second molding portion 320 may include the same material as each other and be integrated with each other, and the difference therebetween may be only in the positions at which they are formed. However, the disclosure is not limited thereto, and as such, the first molding portion 310 and the second molding portion 320 may be formed in a sequential manner, and may include a material different from each.

The molding layer 300 may have a second surface 300S2 coplanar with the second surface 100S2 of the chip 100. In addition, as shown in FIG. 6, an upper surface of the first molding portion 310 and an upper surface of the second molding portion 320 may be coplanar with each other to form a first surface 300S1 of the molding layer 300. The first surface 300S1 of the molding layer 300 may be coplanar with the upper surface of the protective layer PL.

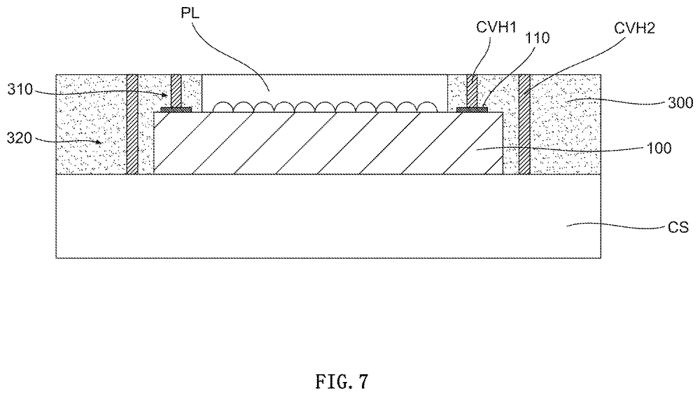

Referring to FIGS. 3 and 7, in operation S140, a first conductive via CVH1 and a second conductive via CVH2 may be formed in the molding layer 300. For example, the first conductive via CVH1 may be formed in the first molding portion 310, and the second conductive via CVH2 may be formed in the second molding portion 320. According to an example embodiment, through holes may be formed in the first molding portion 310 and the second molding portion 320, respectively, using a through mold via (TMV) technique. The TMV technique may include, but is not limited to, dry etching, laser method, or the like. After the through holes are formed, a conductive material may be filled in the through holes to form the first conductive via CVH1 and the second conductive via CVH2. The through holes may be filled by a process, such as electroplating, or the like. The first conductive via CVH1 may extend from the first surface 300S1 of the molding layer 300 to the first surface 100S1 of the chip 100 and is electrically connected to the chip pad 110. The second conductive via CVH2 may extend from the first surface 300S1 of the molding layer 300 to the second surface 300S2 of the molding layer 300.

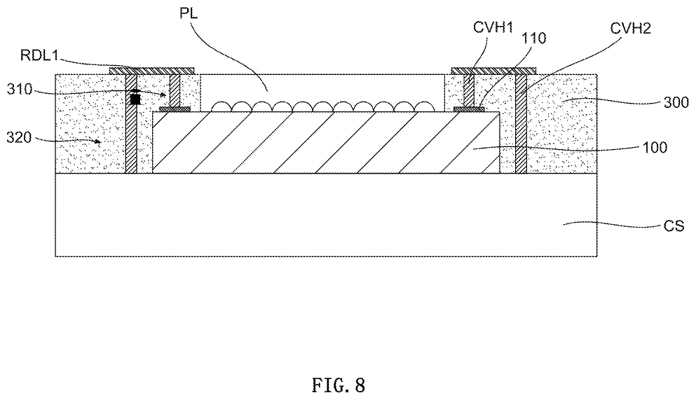

Referring to FIGS. 3 and 8, in operation S150, a first redistribution layer RDL1 may be formed on the first surface 300S1 of the molding layer 300. As described above, only an example in which the first redistribution layer RDL1 includes a single conductive layer is schematically shown in the drawings, but the disclosure is not limited thereto. For example, the first redistribution layer RDL1 may include a plurality of conductive layers and a plurality of insulating layers stacked on each other, and via holes that electrically connect the plurality of conductive layers to each other. In an example embodiment, a preliminary first redistribution layer may be formed by depositing and etching a metal layer on the first surface 300S1 of the molding layer 300 and the upper surface of the protective layer PL. According to another embodiment, a preliminary first redistribution layer may be formed by alternately depositing and etching metal layers and insulating layers on the first surface 300S1 of the molding layer 300 and the upper surface of the protective layer PL. Then, the preliminary first redistribution layer on the protective layer PL may be removed by an etching process to form the first redistribution layer RDL1 on the first surface 300S1 of the molding layer 300 and electrically connected to the first conductive via CVH1 and the second conductive via CVH2.

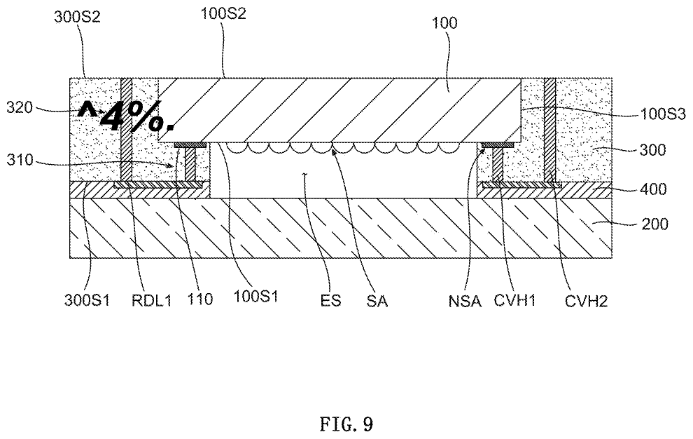

Referring to FIGS. 3 and 9, in operation S160, the protective layer PL and the carrier substrate CS may be removed, and the molding layer 300 may be bonded to a substrate 200 using an adhesive layer 400. In an example embodiment, after removing the protective layer PL and the carrier substrate CS, the molding layer 300 and the chip 100 may be turned over and the first surface 300S1 of the molding layer 300 may be bonded to the substrate 200 using the adhesive layer 400. The adhesive layer 400 may include, but is not limited to a non-conductive film (NCF), a non-conductive paste (NCP), or a capillary underfill (CUF) material. The adhesive layer 400 may have a shape that substantially completely corresponds to the shape of the first surface 300S1 of the molding layer 300.

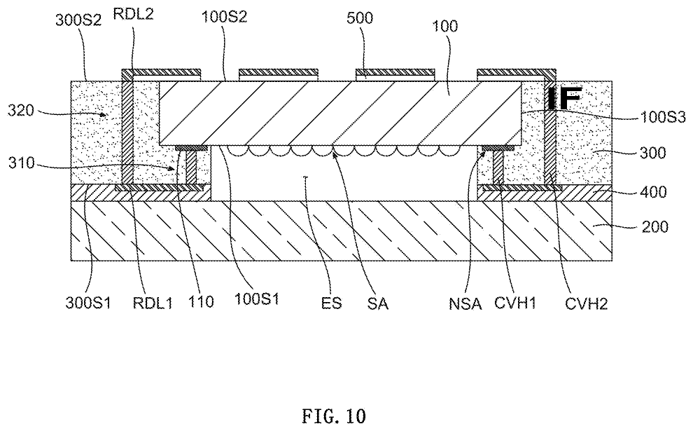

Referring to FIGS. 3 and 10, in operation S170, a second redistribution layer RDL2 may be formed on the second surface 300S2 of the molding layer 300 and the second surface 100S2 of the chip 100. The second redistribution layer RDL2 is also exemplarily shown as a single conductive layer, however, the second redistribution layer RDL2 may include a plurality of conductive layers and a plurality of insulating layers stacked on each other and via holes that electrically connect the plurality of conductive layers to each other. In an example embodiment, the second redistribution layer RDL2 may be formed by depositing and etching a metal layer on the second surface 300S2 of the molding layer 300 and the second surface 10052 of the chip 100. For example, the second redistribution layer RDL2 may be formed by alternately depositing and etching metal layers and insulating layers on the second surface 30052 of the molding layer 300 and the second surface 10052 of the chip 100. The second redistribution layer RDL2 may be electrically connected to the first redistribution layer RDL1 through the second conductive via CVH2.

In addition, as shown in FIG. 10, before forming the second redistribution layer RDL2, a buffer layer 500 may be formed on the second surface 30052 of the molding layer 300 and the second surface 10052 of the chip 100. The buffer layer 500 may be used to improve the bonding force between the second redistribution layer RDL2, and the molding layer 300 and the chip 100 and to insulate the second redistribution layer RDL2 from other elements therebelow. In an example embodiment, the buffer layer 500 may be formed by depositing and etching a preliminary buffer layer on the second surface 30052 of the mold layer 300 and the second surface 10052 of the chip 100. According to another embodiment, the preliminary buffer layer may also be etched together with the metal layers and the insulating layers used to form the second redistribution layer RDL2 to simultaneously form the buffer layer 500 and the second redistribution layer RDL2.

Referring to FIGS. 1 and 3, in operation S180, a solder resist layer 600 and a solder ball 700 may be formed. For example, the solder resist layer 600 having an opening 6000P may be formed by forming a preliminary solder resist layer covering the second redistribution layer RDL2 and the buffer layer 500 on the second surface 300S2 of the molding layer 300 and the second surface 100S2 of the chip 100, and then performing an etching process thereon. Thereafter, the solder ball 700 electrically connected to the second redistribution layer RDL2 through the opening 6000P of the solder resist layer 600 may be formed on the solder resist layer 600. For example the solder balls 700 may be formed on the solder resist layer 600 by a ball grid array (BGA) encapsulation technique.

As described above, by using a photoresist to form the protective layer PL for covering the photosensitive area SA of the chip 100, it is possible to prevent an EMC material from overflowing to the photosensitive area SA of the chip 100 in a method which is relatively easy to implement. In this case, there is no need to use the dam sealing technique to protect the photosensitive area SA of the chip 100, so that defects caused by contamination of the photosensitive area by a sealant used in the dam sealing technique can be avoided, and thus the chip package structure 10 may have improved reliability. In addition, since there is no need to use the dam sealing technique and no need to add additional members in the chip package structure 10, the manufacturing process of the chip package structure 10 can be simplified.

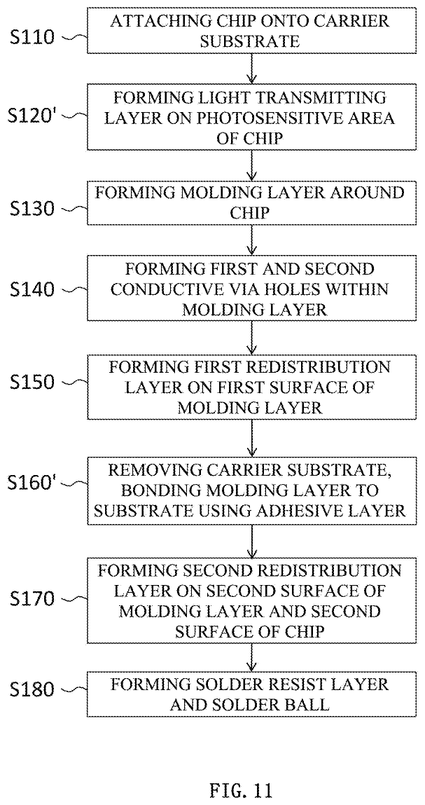

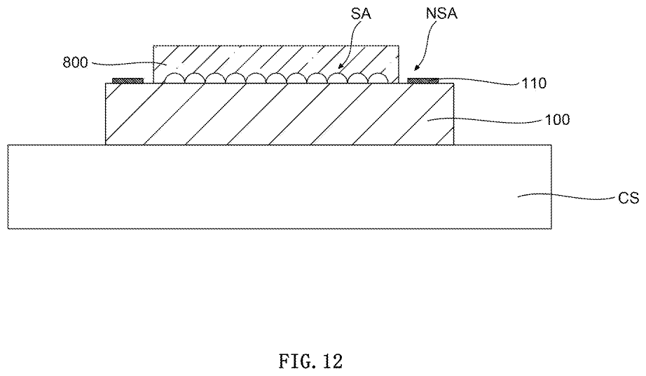

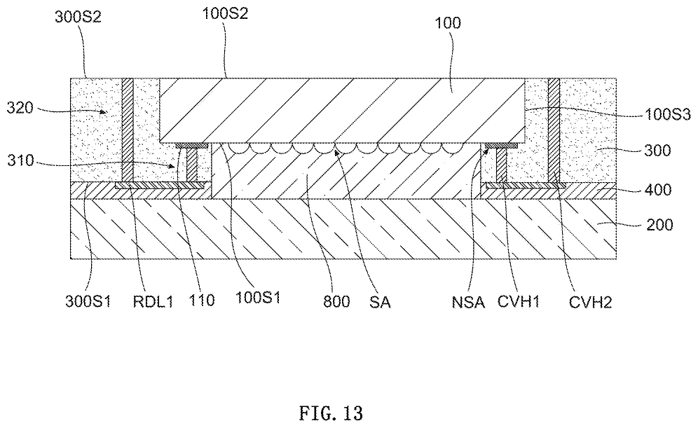

FIG. 11 is a flowchart illustrating a method of manufacturing the chip package structure according to another example embodiment of the disclosure. FIGS. 12 to 13 are cross-sectional views illustrating operations of the method of manufacturing the chip package structure according to another example embodiment of the disclosure. In FIGS. 12 to 13, reference numerals identical to those in FIG. 2 are used to refer to identical elements, and therefore, redundant descriptions are not repeated.

The method of manufacturing the chip package structure shown in FIGS. 11 to 13 corresponds to the chip package structure 10-1 shown in FIG. 2.

Referring to FIGS. 11 and 12, in operation S120′, a light transmitting layer 800 is formed on the photosensitive area SA of the chip 100. The light transmittance layer 800 may include or be composed of a material having a high light transmittance. The light transmitting layer 800 is provided on the photosensitive area SA of the chip 100, that is, covers the photosensitive area SA of the chip 100.

Referring to FIGS. 11 and 13, in operation S160′, only the carrier substrate CS is removed without removing the light transmitting layer 800. The molding layer 300 may be bonded to the substrate 200 using the adhesive layer 400. As such, the light transmitting layer 800 may contact one surface (e.g. the upper surface in FIG. 1) of the substrate 200 and the inner surface of the molding layer 300.

Other operations in the method of manufacturing the chip package structure shown in FIGS. 11 to 13 are the same as corresponding operations in the method of manufacturing the chip package structure shown in FIGS. 3 to 10, and the redundant description will not be repeated here.

As described above, by forming the light transmitting layer 800 covering the photosensitive area SA on the first surface 100S1 of the chip 100, it is possible to prevent the EMC material from overflowing to the photosensitive area SA of the chip 100 informing the molding layer 300. Therefore, there is no need to use the dam sealing technique to protect the photosensitive area SA of the chip 100, so that defects caused by contamination of the photosensitive area by a sealant used in the dam sealing technique can be avoided. In addition, in the manufacturing process of the chip package structure 10-1, the operation of removing the light transmitting layer 800 is not required, and thus the manufacturing process can be simplified.

According to an embodiment of the disclosure, by forming a protective layer or a light transmitting layer on the photosensitive area of the chip, it is possible to prevent an EMC material from overflowing to the photosensitive area of the chip during forming the molding layer. Therefore, the fan-out CIS chip package structure can be realized without using dam sealing technique. Accordingly, defects caused by contamination of the photosensitive area by a sealant can be avoided, and thus the chip package structure may have improved reliability and simplified structure and manufacturing process.

Although the disclosure has been specifically shown and described with reference to some example embodiments thereof, it will be understood that various changes in form and detail may be made therein without departing from the spirit and scope of the appended claims.

1. A semiconductor chip package comprising:
a substrate;
a semiconductor chip provided on the substrate and spaced apart from the substrate, the semiconductor chip having a first surface facing the substrate, a second surface facing a direction opposite to the first surface, and a side surface connecting the first surface and the second surface, the first surface of the semiconductor chip comprising a first area and a second area surrounding the first area;
a molding layer having a first surface facing the substrate and a second surface opposite to the first surface, the molding layer provided on the second area of the semiconductor chip and the side surface of the semiconductor chip; and
an adhesive layer provided between the substrate and the molding layer.

2. The semiconductor chip package of claim 1,
wherein the first area is a photosensitive area and the second area is a non-photosensitive area, and
wherein the semiconductor chip comprises a pad in the non-photosensitive area.

3. The semiconductor chip package of claim 2, further comprising:
a first conductive via extending from the first surface of the molding layer to the first surface of the semiconductor chip in a first molding portion of the molding layer, and electrically connected to the pad; and
a second conductive via extending from the first surface of the molding layer to the second surface of the molding layer in a second molding portion of the molding layer,
wherein the first molding portion is provided on the second area of the semiconductor chip and the second molding portion is provided to surround the side surface of the semiconductor chip, and the first molding portion, and
wherein the second molding portion being integrated with each other.

4. The semiconductor chip package of claim 3, further comprising:
a first redistribution layer provided on the first surface of the molding layer and configured to electrically connect the first conductive via and the second conductive via to each other.

5. The semiconductor chip package of claim 4, further comprising:
a second redistribution layer provided on the second surface of the molding layer and electrically connected to the first redistribution layer through the second conductive via.

6. The semiconductor chip package of claim 5, further comprising:
a buffer layer between the second surface of the molding layer and the second surface of the semiconductor chip, and the second redistribution layer.

7. The semiconductor chip package of claim 6, further comprising:
a solder resist layer on the second surface of the molding layer, the second surface of the semiconductor chip, the second redistribution layer and the buffer layer, the solder resist layer having an opening configured to expose a portion of the second redistribution layer.

8. The semiconductor chip package of claim 7, further comprising:
a solder ball on the solder resist layer and electrically connected to the second redistribution layer through the opening of the solder resist layer.

9. The semiconductor chip package of claim 1, further comprising:
an empty space between the first area of the semiconductor chip and the substrate.

10. The semiconductor chip package of claim 2, further comprising:
a light transmitting layer between the first area of the semiconductor chip and the substrate.

11. The semiconductor chip package structure of claim 1, wherein the second surface of the molding layer and the second surface of the semiconductor chip are coplanar with each other.

12. The semiconductor chip package structure of claim 3, wherein a surface of the first molding portion facing the substrate and a surface of the second molding portion facing the substrate are coplanar with each other to form the first surface of the molding layer and contact a surface of the adhesive layer.

13-23. (canceled)
